(19) United States
(12) Patent Application Publication
(10) Pub. No.: US 2024/0339426 A1
(43) Pub. Date: Oct. 10, 2024

(54) LEADLESS SEMICONDUCTOR PACKAGE WITH DUAL-SIDED STUD STRUCTURE FOR DIE-TO-PACKAGE FAN OUT

(71) Applicant: NXP B.V., Eindhoven (NL)

(72) Inventors: Wen Yuan CHUANG, Kaohsiung (TW); Kuan-Hsiang MAO, Kaohsiung (TW); Wen Hung HUANG, Kaohsiung (TW)

(21) Appl. No.: 18/131,929

(22) Filed: Apr. 7, 2023

(51) Int. Cl. H01L 23/00; H01L 21/56; H01L 23/31

(52) U.S. Cl. CPC H01L 24/16; H01L 21/565; H01L 23/3135; H01L 24/11; H01L 24/96; H01L 2224/11825; H01L 2224/16058; H01L 2224/16059; H01L 2224/16225; H01L 2224/96; H01L 2924/182

(57) ABSTRACT

A leadless semiconductor package includes an integrated circuit (IC) die having one or more contacts at an active surface facing a mounting surface of the leadless semiconductor package. The leadless semiconductor package further includes a plurality of dual-sided stud structures providing electrical connectivity between the IC die and the mounting surface, each dual-sided stud structure having at least one first conductive pillar structure extending from a corresponding contact at the active surface to a redistribution layer and having at least one second conductive pillar structure extending from a redistribution layer to an edge of the mounting surface, each first conductive pillar structure having a first dimension in a direction parallel to the mounting surface that is less than a corresponding second dimension of each second conductive pillar structure. Solder wettable flanks may be formed at the external sidewall edges of the second conductive pillar structures to facilitate soldering or inspection.

### BACKGROUND

Flat leadless packages, such as quad-flat no-leads (QFN) packages and dual-flat no-leads (DFN) packages, are surface mount (SMT) semiconductor packages that encapsulate one or more integrated circuit (IC) die and provide electrical connections between the IC die and a printed circuit board (PCB) or other circuit board via conductive structures extending from the IC die to conductive pads (or lands) on the “bottom” surface of the package. In some conventional packaging technologies, these conductive structures utilize either wire bonds and a lead frame or one or more redistribution layers (RDLs) to fan-out connections from the IC die to corresponding pads at the “bottom surface” of the package. However, conventional fan-out approaches utilizing RDLs often result in package surface mount pads that are relatively thin and thus difficult to fabricate with solder wettable sidewalls. The resulting package thus may be unsuitable for use automotive, aeronautic, and other high-reliability implementations in which leads with wettable sidewalls provide for both improved solder distribution as well as providing a visual reference for the quality of solder joints during device inspection.

### SUMMARY OF EMBODIMENTS

The present disclosure may be better understood with reference to the following examples, which may be considered individually or in various combinations.

Example 1: A leadless semiconductor package including an integrated circuit (IC) die having one or more contacts at an active surface facing a mounting surface of the leadless semiconductor package, and a plurality of dual-sided stud structures providing electrical connectivity between the IC die and the mounting surface, each dual-sided stud structure having at least one first conductive pillar structure extending from a corresponding contact at the active surface to a redistribution layer and having at least one second conductive pillar structure extending from a redistribution layer to an edge of the mounting surface, each first conductive pillar structure having a first dimension in a direction parallel to the mounting surface that is less than a corresponding second dimension of each second conductive pillar structure.

Example 2: The leadless semiconductor package of Example 1, further including encapsulant material at least partially encapsulating the IC die and the plurality of dual-sided stud structures.

Example 3: The leadless semiconductor package of Example 2, wherein the encapsulant material includes a first encapsulant layer encapsulating the active surface of the IC die and the first pillar structures of the plurality of dual-sided stud structures, and a second encapsulant layer encapsulating the second pillar structures of the plurality of dual-sided stud structures and forming a portion of the mounting surface.

Example 4: The leadless semiconductor package of Example 1, wherein each second conductive pillar structure includes a solder wettable flank at an exterior sidewall.

Example 5: The leadless semiconductor package of Example 4, further including solder plating on exterior surfaces of the second conductive pillar structures that are parallel to the mounting surface and on surfaces of the solder wettable flanks of the second conductive pillar structures.

Example 6: The leadless semiconductor package of Example 1, wherein the second dimension is at least two times larger than the first dimension.

Example 7: The leadless semiconductor package of Example 1, wherein the second dimension is at least three times larger than the first dimension.

Example 8: An electronic device including a circuit board having the leadless semiconductor package of Example 1 mounted thereon.

Example 9: A leadless semiconductor package including a first surface and an opposing second surface, an integrated circuit (IC) die disposed adjacent to the first surface, and a conductive fan-out structure to provide contact fan-out from a plurality of contacts of an active surface of the IC die to the second surface of the leadless semiconductor package, the conductive fan-out structure including a plurality of thick pillar structures, each thick pillar structure extending into the leadless semiconductor package from an edge of the second opposing surface, wherein exposed surfaces of the thick pillar structures serve as surface mounting pads for the leadless semiconductor package, and a plurality of thin pillar structures, each thin pillar structure extending into the leadless semiconductor package from a corresponding contact of the plurality of contacts and electrically connected to at least one thick pillar structure via at least one redistribution layer, wherein the thick pillar structures are at least two times as thick as the thin pillar structures.

Example 10: The leadless semiconductor package of Example 9, wherein each second conductive pillar structure includes a solder wettable flank formed at an exterior sidewall.

Example 11: The leadless semiconductor package of Example 9, further including at least one encapsulant layer encapsulating the plurality of thin pillar structures and the plurality of thick pillar structures.

Example 12: An electronic device including a circuit board having the leadless semiconductor package of Example 9 mounted thereon.

Example 13: A method of fabricating a leadless semiconductor package, the method including forming a plurality of first pillar structures extending from contacts at an active surface of an integrated circuit (IC) die, encapsulating the IC die and the plurality of first pillar structures in a first encapsulant layer, forming one or more redistribution layers at a surface of the first encapsulant layer opposite the IC die, the one or more redistribution layers having metallizations electrically and mechanically connected to one or more corresponding first pillar structures of the first plurality of pillar structures, forming a plurality of second pillar structures extending from the one or more redistribution layers, each second pillar structure electrically connected to one or more first pillar structures via at least one redistribution layer and having a second dimension in a direction parallel to the active surface that is greater than a corresponding first dimension of each first conductive pillar structure, encapsulating the plurality of second pillar structures in a second encapsulant layer, and planarizing the second encapsulant layer and the plurality of second pillar structures to form a mounting surface for the leadless semiconductor package with exposed surfaces of the plurality of the second pillar structures serving as surface mount pads for the leadless semiconductor package.

Example 14: The method of Example 13, further including forming solder wettable flanks in exposed sidewalls of the plurality of second pillar structures.

Example 15: The method of Example 14, further including solder plating exposed surfaces of the plurality of the second pillar structures including the solder wettable flanks.

Example 16: The method of Example 14, further including forming a reconstructed panel including a plurality of workpieces including a workpiece representing the leadless semiconductor package, singulating the reconstructed panel after planarizing the second encapsulant layer and the plurality of second pillar structures to generate a plurality of leadless semiconductor packages from the plurality of workpieces, and wherein forming the solder wettable flanks includes forming grooves along singulation lines in metal material representing second pillar structures from adjacent workpieces prior to singulating the reconstructed panel.

Example 17: The method of Example 16, wherein forming grooves includes at least one of: performing chemical etches to form the grooves, or performing singulation cuts to partial depth to form the grooves.

Example 18: The method of Example 13, wherein the second dimension is at least two times the first dimension.

Example 19: The method of Example 13, wherein the second dimension is at least three times the first dimension.

Example 20: A leadless semiconductor package formed in accordance with the method of Example 13.

### BRIEF DESCRIPTION OF THE DRAWINGS

The present disclosure also is better understood, and its numerous features and advantages made apparent to those skilled in the art, by referencing the accompanying drawings. The use of the same reference symbols in different drawings indicates similar or identical items.

FIG. 1 is a diagram illustrating cross-section view of a leadless semiconductor package utilizing dual-sided stud structures for connection fan-out in accordance with some embodiments.

FIG. 2 is a diagram illustrating a bottom view of the leadless semiconductor package of FIG. 1 in accordance with some embodiments.

FIG. 3 is a diagram illustrating a cross-section view of an electronic device having the leadless semiconductor package of FIGS. 1 and 2 mounted on a circuit board in accordance with some embodiments.

FIGS. 4 and 5 are diagrams that together illustrate a method of fabrication of a leadless semiconductor package having dual-sided stud structures in accordance with some embodiments.

### DETAILED DESCRIPTION

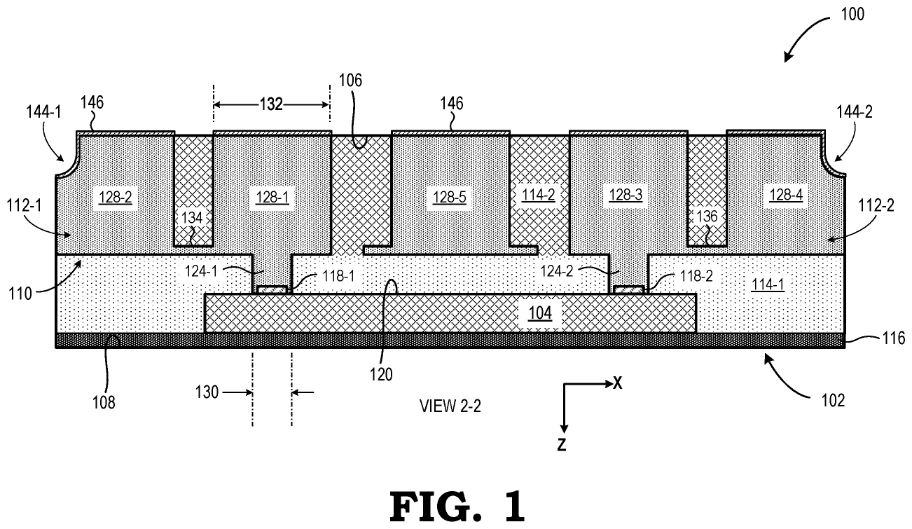

Conventional QFN, DFN, and other flat no-lead semiconductor package configurations utilize either wire bonding structures or RDL structures that often lead to surface mount pads that are not well suited for sidewall wettability. Moreover, these conventional fan-out structures often do not provide significant mechanical or structural support for the semiconductor package. They also often do not provide significant radio frequency (RF) or other electromagnetic (EM) insulation from the circuit board to which the package is mounted. FIGS. 1-5 below illustrate embodiments of a leadless semiconductor package (e.g., a QFN or DFN) having dual-sided stud structures that enable contact fan-out between an IC die and the mounting surface of the package, while also providing surface mount pads with wettable sidewalls and which provide mechanical support and EM isolation for the package. Each dual-sided stud structure includes at least one conductive “thin” pillar structure extending from a contact on the active surface of the embedded IC die to one or more RDL metallizations (e.g., metal lines/traces and/or vias) of the package, and further includes at least one conductive “thick” pillar structure extending from the one or more RDL metallizations to the mounting surface of the package. The thin pillar structures(s), thick pillar structures(s), and one or more RDL metallizations are electrically and mechanically connected, thereby forming one or more conductive paths between the contact(s) on the active surface and the mounting surface of the IC package. The thin pillar structures of the dual-sided stud structures have lateral dimension(s) compatible with the dimension scale of the active surface of the IC die and contacts thereon, while the thick pillar structures of the dual-sided stud structures have significantly larger lateral dimension(s) compatible with the significantly larger dimensional scale of the mounting surface of the package. This allows the dual-sided stud structures to provide die-to-package surface contact fanout, while also allowing the thick pillar structures to be processed at the mounting surface to incorporate solder wettable flanks along their exposed sidewall edges so as to facilitate sidewall wettability. Moreover, this thin-to-thick dual-sided stud structure provides for improved mechanical rigidity of the IC package, while also providing for EM isolation due to the relative height of the dual-sided stud structures as well as the volume of EM-insulating metal they provide between the IC die and the mounting surface of the package.

Note that in the following, certain orientational terms, such as top, bottom, front, back, lateral, vertical, thin, thick, wide, and the like, are used in a relative sense to describe the positional relationship of various components. These terms are used with reference to the relative position of components either as shown in the corresponding figure or as used by convention in the art and are not intended to be interpreted in an absolute sense with reference to a field of gravity. Thus, for example, a surface shown in the drawing and referred to as a top surface of a component would still be properly understood as being the top surface of the component, even if, in implementation, the component was placed in an inverted position with respect to the position shown in the corresponding figure and described in this disclosure. Further, note that certain positional terms, such as co-planar or parallel, will be understood to be interpreted in the context of fabrication tolerances or industry standards. For example, co-planar shall be understood to mean co-planar within applicable tolerances as a result of one or more fabrication processes affecting the components indicated to be co-planar, or co-planar within a tolerance utilized in the appropriate industry or fabrication technology. Moreover, it will be appreciated that for simplicity and clarity of illustration, components shown in the figures have not necessarily been drawn to scale. For example, the dimensions of some of the components may be exaggerated relative to other components in order to facilitate understanding of associated aspects.

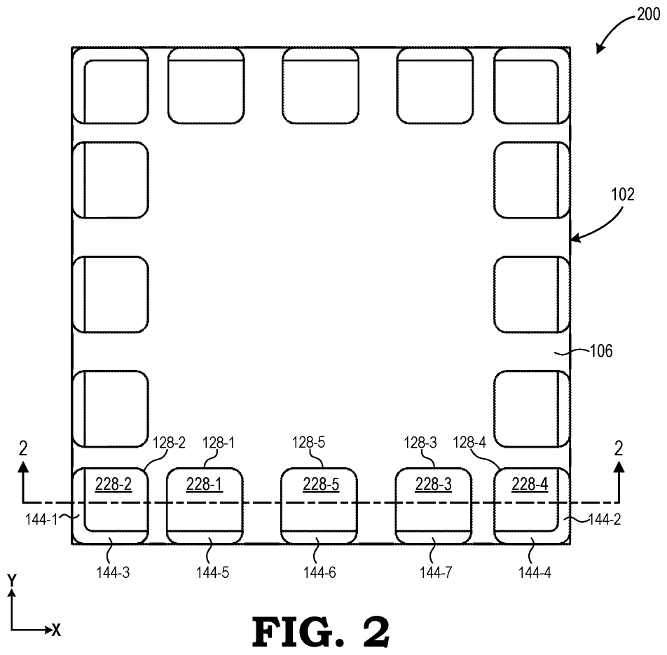

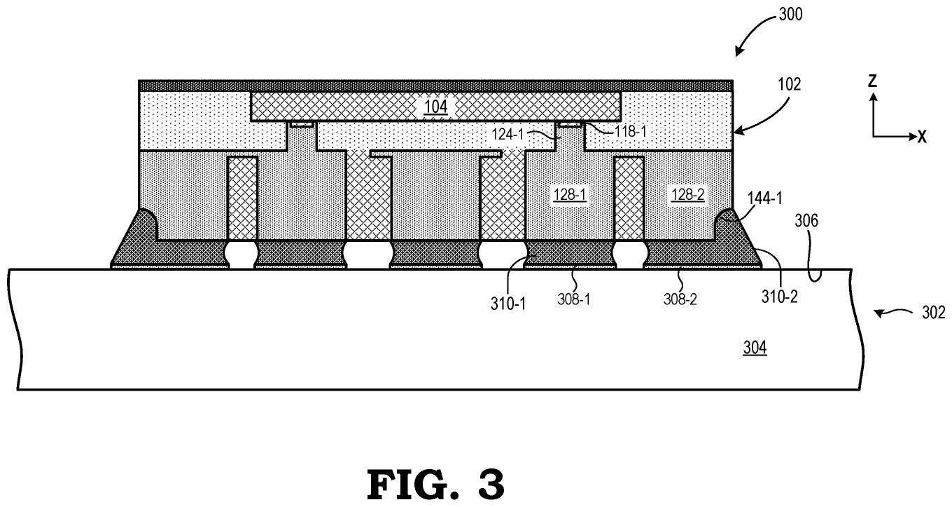

FIG. 1 illustrates a cross-section view 100 along a cutline 2-2 (FIG. 2) of a leadless semiconductor package 102 (hereinafter, “package 102”) employing dual-sided stud structures for die-to-surface fan-out connectivity and package surface mounting in accordance with some embodiments. The package 102 encapsulates one or more IC die 104 and is configured to surface mount to a printed circuit board (PCB) or other circuit board of an electronic device (see FIG. 3). In particular, the package 102 implements a flat, no-lead package configuration in which the surface mount pads (or “leads”) are implemented on the periphery of a bottom surface 106 of the package 102, such as a QFN package configuration.

As shown, the package 102 has the bottom surface 106 and an opposing surface 108, with the bottom surface 106 serving as the mounting surface by which the package 102 is mounted to a PCB or other circuit board of an electronic device (not shown in FIG. 1). As such, the bottom surface 106 is referred to herein as the “mounting surface 106” and the opposing surface 108 referred to herein as the “top surface 108.” In the depicted embodiment, the package 102 is composed of a stack of structures/layers, including the one or more IC die 104, a fan-out structure 110 comprising one or more dual-sided stud structures 112 (such as the illustrated dual-sided stud structures 112-1 and 112-2), and one or more encapsulant layers 114 (such as the illustrated encapsulant layers 114-1 and 114-2) extending between the mounting surface 106 and the top surface 108 of the package 102. Further, in some embodiments, a backside lamination (BSL) layer 116 may be disposed at the top surface 108.

The fan-out structure 110 utilizes the one or more dual-sided stud structures 112 to provide fan-out electrical connectivity between contacts 118 (e.g., contacts 118-1 and 118-2) at an active surface 120 of the IC die 104 and corresponding surface mount pads (see FIG. 2) at the mounting surface 106 of the package 102. Each dual-sided stud structure 112 includes at least one first pillar structure 124 extending between a corresponding contact 118 and a facing metallization (e.g., a metal line or trace) of one or more RDLs of the package 102, and at least one second pillar structure 128 extending from the mounting surface 106 and a facing metallization of the one or more RDLs of the package 102. The first pillar structures (s) 124, the second pillar structures(s) 128, and trace(s), via(s), and other metallizations of the RDL(s) electrically and mechanically connect the first pillar structures (s) to the second pillar structures (s) in a given dual-sided stud structure 112 are composed of one or more metals, metal alloys, or oxides thereof, other conductive materials, or combinations thereof, such as copper (Cu), aluminum (Al), silver (Ag), gold (Au), titanium (Ti), and alloys (e.g., an iron (Fe)-nickel (Ni) alloy), or oxides thereof.

The first pillar structures 124 and second pillar structures 128 can have any of a variety of cross-sectional shapes, including a circular or elliptical cross-section, a substantially rectangular cross-section, a stadium (or pill-shaped) cross-section, an n-sided polygonal cross-section, or the like, and the cross-section shape employed for the first pillar structures 124 may be the same or different from that employed for the second pillar structures 128. To facilitate die-to-package fan-out, the first pillar structures 124 have lateral dimensions suitable to the lateral dimensional scale of the active surface 120 of the IC die 104, whereas the second pillar structures 128 have lateral dimensions suitable to the lateral dimensional scale of the mounting surface 106 of the package 102. For purposes of this disclosure, the term “lateral” refers to a direction parallel to either or both of the plane formed by the active surface 120 of the IC die 104 or the plane formed by the mounting surface 106 of the package 102. For example, the second pillar structures 128 may have a second lateral dimension 132 in the indicated X-direction that is substantially larger than the corresponding first lateral dimension 130 of the second pillar structure 128 in the X-direction. In some embodiments, substantially larger in this sense means at least 50% larger (that is, the second lateral dimension 132>=150% of the first lateral dimension 130). In other embodiments, substantially larger in this sense means at least twice as large (that is, the second lateral dimension 132>=200% of the first lateral dimension 130). In still other embodiments, substantially larger in this sense means at least three times as large (that is, the second lateral dimension 132>=300% of the first lateral dimension 130). To put it another way, the second pillar structures 128 have a cross-sectional area substantially greater than a cross-sectional area of the first pillar structures 128, such as, in some embodiments, at least twice the cross-sectional area, and in other embodiments, at least three times the cross-sectional area. Accordingly, the first pillar structures 124 are referred to herein as “thin pillar structures 124” and the second pillar structures 128 are referred to herein as “thick pillar structures 128” in view of the relative difference in their corresponding lateral dimensions.

To illustrate, in the depicted example of FIG. 1, the dual-sided stud structure 112-1 includes a thin pillar structure 124-1 extending between (and electrically coupled to) a contact 118-1 at the active surface 120 and a thick pillar structure 128-1. The thick pillar structure 128-1 extends between the RDL(s) of the package and the mounting surface 106. The dual-sided stud structure 112-1 further includes another thick pillar structure 128-2 electrically and mechanically coupled to the thin pillar structure 124-1 and the thick pillar structure 128-1 via a metal trace 134 (one example of an RDL metallization) of an RDL of the package 102. The dual-sided stud structure 112-2 includes a thin pillar structure 124-2 extending between (and electrically coupled to) a contact 118-2 at the active surface 120 and a thick pillar structure 128-3. The thick pillar structure 128-3 extends between the RDL(s) of the package and a corresponding edge of the mounting surface 106. The dual-sided stud structure 112-2 further includes another thick pillar structure 128-4 electrically and mechanically coupled to the thin pillar structure 124-2 and the thick pillar structure 128-3 via a metal trace 136 of an RDL of the package 102. The exposed external surfaces of the thick pillar structures 128-1, 128-2 and 128-3, 128-4 at the mounting surface 106 and sidewalls of the package 102 thus form the surface mount pads (also known as “terminal pads” or “mounting pads”) for electrically and mechanically coupling the dual-sided stud structures 112-1 and 112-2, respectively, to corresponding pads of a PCB or other circuit board. The example cross-section view 100 also depicts a fifth thick pillar structure 128-5, which may be part of a third dual-sided stud structure 112 that extends in the Y-direction relative to the X-Z orientation of cross-section view 100, or which may be implemented as a dummy stud for heat transfer, mechanical integrity, or EM isolation purposes.

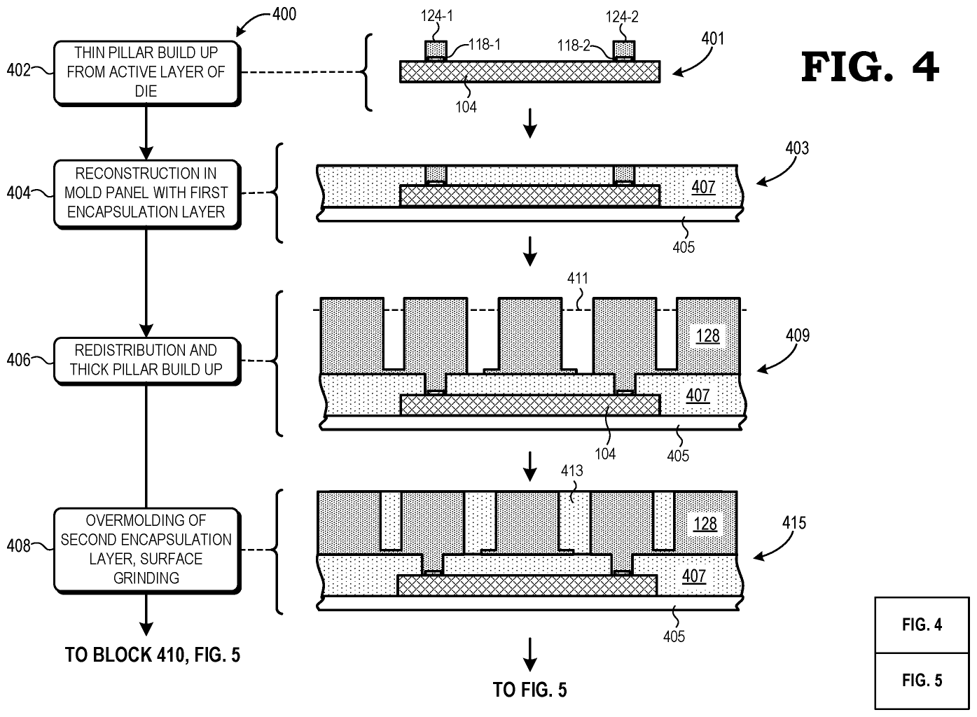

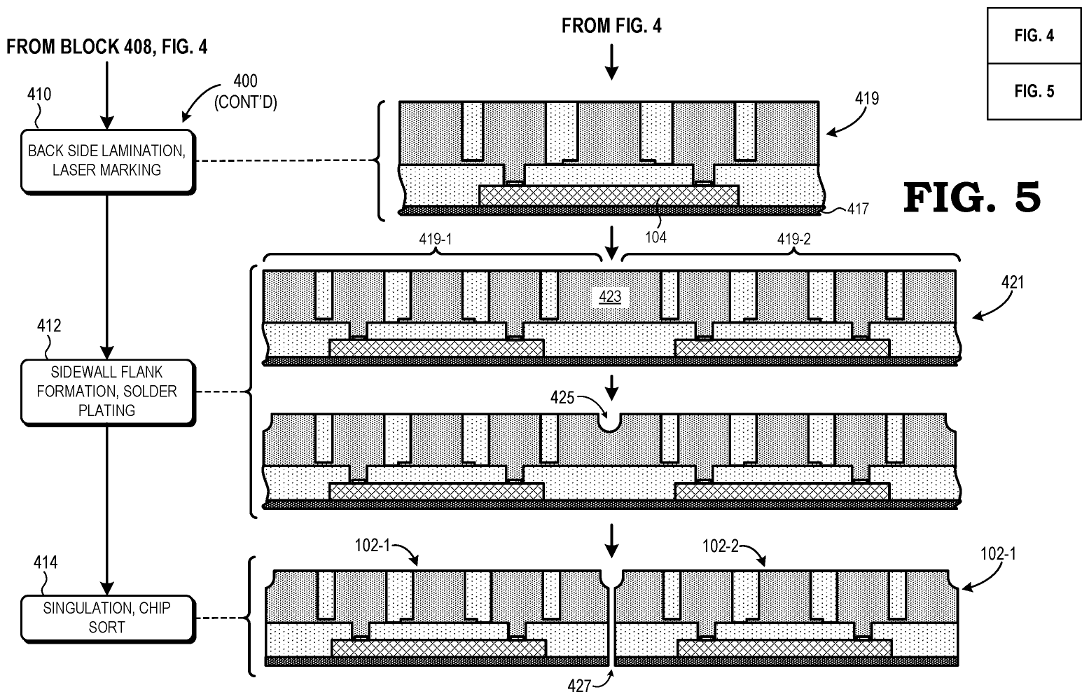

The package 102 further includes one or more encapsulant layers 114 to encapsulate the IC die 104, the thin pillar structures 124, the thick pillar structures 128, and the one or more RDLs. As described in greater detail below with reference to FIGS. 4 and 5, in at least one embodiment the package 102 is fabricated using two molding steps: a first molding step in which the thin pillar structures 124 are formed at the active surface of the IC die 104 and then the IC die 104 and thin pillar structures 124 are encapsulated in a first encapsulant layer (e.g., encapsulant layer 114-1) and, subsequently, a second molding step in which the thick pillar structures 128 and RDL are encapsulated in a second encapsulant layer (e.g., encapsulant layer 114-2), which forms a portion of the mounting surface 106 along with the exposed “top” surfaces of the thick pillar structures 128. The encapsulant(s) employed in these one or more encapsulant layers can include any of a variety of suitable encapsulant materials or combination thereof, such as plastics, epoxy resins, ceramics, and the like. It should be noted that reference to a structure being “encapsulated” by an encapsulant or encapsulant layer does not require that the structure be wholly encapsulated by the encapsulant or encapsulant layer. To illustrate, the encapsulant layer 114-2 is described as encapsulating the thick pillar structures 128 even though the top surface and at least one side surface of each thick pillar structure is not covered or concealed in encapsulant, that is, the top surface and at least one side surface is exposed to the outside of the package 102 (or, in some embodiments, such otherwise exposed surfaces are plated with solder plating, as described below)

The implementation of the dual-sided stud structures 112 for contact fan-out from the active surface 120 of the IC die 104 to the comparably larger mounting surface 106 of the package 102 results in the thick pillar structures 128 serving as the surface mount pads for establishing mechanical and electrical connections between a circuit board and the package 102 mounted thereon. The relatively long vertical dimensions (that is, dimensions parallel to a plane orthogonal to the active surface 120 or mounting surface 106, or along the indicated Z-direction) of these thick pillar structures 128 thus facilitate sidewall wetting during the soldering process. Moreover, due to their relatively thick lateral dimensions, during the fabrication process wettable sidewall flanks 144, such as sidewall flanks 144-1 and 144-2, can be formed in the exterior sidewalls of the thick pillar structures 128. These sidewall flanks 144 are formed as rabbets in the edges of the sidewall of the thick pillar structures 128 and facilitate sidewall wettability by facilitating formation of a side solder fillet that can be visually inspected more readily. To further improve solderability, in some embodiments the external surfaces of the thick pillar structures 128 can be finished in an appropriate solder plating layer 146, such as a plating of tin (Sn), gold (Au), or the like.

Not only does the use of relatively thick and tall pillar structures facilitate sidewall wettability, these thick pillar structures 128 also provide for enhanced structural rigidity by virtue of their size and volume of rigid conductive material, and thus better protect the integrity of the package 102. For similar reasons, the dual-sided stud structures 112 provide enhanced EM isolation for the IC die 104 in the presence of potential EM interference from the circuit board or other components mounted thereon.

FIG. 2 illustrates a bottom view 200 of the package 102 in accordance with some embodiments. As described, the mounting surface 106 is formed from a bottom surface of the package encapsulant layer 114-2 along with the exposed “bottom” surfaces of the thick pillar structures 128 of the dual-sided stud structures 112 (and, in some instances, separate dummy thick pillar structures). As the bottom exterior surfaces of the thick pillar structures 128 are co-planar, or flush, with the mounting surface 106 and thus exposed through the package encapsulant 114 at the mounting surface 106, the bottom exterior surfaces of the thick pillar structures 128 serve as surface mount pads 228 at the perimeter of the package 102, such as the bottom exterior surfaces of the thick pillar structures 128-1 to 128-5 serving as surface mount pads 228-1 to 228-5, respectively. Moreover, as at least one side surface of the thick pillar structures 128, or “sidewall”, is co-planar with a corresponding side surface of the package 102 and thus exposed, the exposed sidewalls of the thick pillar structures 128 may serve as wettable sidewalls for soldering purposes. This sidewall wettability may be further enhanced by the sidewall flanks 144 formed in the external-facing sides of the thick pillar structures 128, such as the sidewall flanks 144-1 and 144-2 in the thick pillar structures 128-2 and 128-4 as previously illustrated in cross-section view 100 of FIG. 1, respectively, as well as the sidewall flanks 144-3, 144-4, 144-5, 144-6, and 144-7 formed in the thick pillar structures 128-2, 128-4, 128-1, 128-5, and 128-3, respectively, along the bottom edge of the package 102. Note that although a surface mount pad configuration having five surface mount pads 228 to a side (for a total of 16 surface mount pads 228) is illustrated, it will be appreciated that a semiconductor package fabricated in accordance with the teachings provided herein can include any of a variety of pad number/array configurations.

FIG. 3 illustrates a cross-section view 300 of an electronic device 302 having a circuit board 304 with the package 102 mounted thereon in accordance with at least some embodiments. As illustrated, the package 102 is surface mounted to the circuit board 304. Accordingly, the package 102 is positioned and oriented such that the mounting surface 106 of the package 102 faces a corresponding surface 306 of the circuit board 304. Each of at least a subset of the package surface mount pads 228 formed by the external surface of a corresponding thick pillar structure 128 of a double-sided stud structure 112 is electrically and mechanically connected to a corresponding pad of the circuit board 304 via a corresponding solder bump or other conductive structure, and thus providing an electrically conductive path between the pad and circuitry of the IC die 104 via the conductive components of the double-sided stud structure 112. For example, the thin pillar structure 124-1 and the thick pillar structures 128-1 and 128-2 of the double-sided stud structure 128-1 and the solder bumps 310-1 and 310-2 form conductive pathways between the contact 118-1 of the IC die 104 and pads 308-1 and 308-2, respectively, of the circuit board 304. As also illustrated by solder bump 310-2, the sidewall flanks 144 (e.g., sidewall flank 144-1) formed in the external peripheral sides of the thick pillar structures 128 facilitates sidewall solder wetting and thus not only facilitates improved solder joints but also facilitates visual inspection of such solder joints. Further, although not depicted for ease of illustration, a dielectric underfill material may be deposited between the package 102 and the circuit board 304 to provide a stronger mechanical bond and to further isolate the individual electrical connections between the package 102 and the circuit board 304.

FIGS. 4 and 5 together illustrate a method 400 of fabrication of a leadless semiconductor package employing conductive dual-sided stud structures for fan-out die-to-surface connectivity and package surface mounting in accordance with some embodiments. For ease of illustration, the method 400 is described with reference to the package 102 of FIGS. 1-3, but the method 400 is not limited to this example description. Moreover, at least by virtue of their ability to be built-up layer-by-layer, the use of the double-sided stud structures 112 allows the resulting semiconductor package to be readily fabricated using a fan-out panel-level-packaging (FO-PLP) process, and thus the fabrication process of method 400 will be described in the context of a PLP fabrication process. However, it will be appreciated that other packaging processes, such as wafer-level packaging (WLP) processes may be employed to fabricate similar semiconductor packages using the guidelines provided herein.

The method 400 initiates with the fabrication or other obtainment of a workpiece 403 implementing the IC die 104. To illustrate, in some embodiments, a wafer containing a plurality of instances of the IC die 104 is fabricated, tested, and singulated to generate a plurality of instances of tested, known-good IC die 104, from which the particular IC die 104 of workpiece 401 is selected. At block 402, one or more processes are performed to build-up or otherwise form the thin pillar structures 124 aligned with, and in electrical and mechanical contact with, the contacts 118 of the active surface 120 of the IC die 104. Any of a variety of fabrication processes known in the art can be utilized to form the thin pillar structures 124, such as processes that utilize chemical vapor deposition (CVD), physical vapor deposition (PVD), photolithographic-based masking and etching, laser or mechanical drilling, metal sputtering, metal plating, and the like. For example, in some implementations, the thin pillar structures 124 are formed from a series of processes, including a film lamination process, a laser drilling process, a sputtering process to deposit a combination of titanium (Ti) and copper (Cu) in the holes and then a corresponding develop process, followed by a copper plating process.

In a FO-PLP process, a round or rectangular panel of IC dice is reconstructed from a plurality of separate and individual IC dice via a pick-and-place process that positions a plurality of IC dice in an array formation within a mold panel and then a molding process is performed to form at least an initial molding, or encapsulant, layer. Accordingly, at block 404, a plurality of instances of the workpiece 401 are reconstructed into a large mold frame having a panel carrier 405 and the plurality of instances of the workpiece 401 then are overmolded in an encapsulant (or “molding compound”), such as epoxy, resulting in a reconstructed panel having an array of instances of workpiece 403 composed of the workpiece 401 (the IC die 104 and the built-up thin pillar structures 124) encapsulated in a first encapsulant layer 407 (which, after singulation as described below, becomes the first encapsulant layer 114-2).

At block 406, any of a variety of well-known redistribution processes are performed on the resulting workpiece 409 (as part of the reconstructed panel) to form the metallizations and insulating layer(s) of the one or more RDLs to be implemented in the resulting package. Thereafter, one or more processes are performed to build up the thick pillar structures 128 of the double-sided stud structures. Such processes can include one or more CVD processes, PVD processes, photolithographic mask/etch processes, laser drilling or mechanical drilling processes, sputtering processes, plating processes, and the like. In some embodiments, a surface grind process or similar process is performed to planarize the “top” surface of the workpiece to create a more planar mounting surface for the resulting package. In such instances, the build-up of the thick pillar structures 128 can include over-building the height (“vertical” dimension) of the thick pillar structures 128 beyond their final intended height (as represented by line 411) so as to compensate for the loss of material at the “top” of the thick pillar structures 128 as a result of the surface grind process. The metallizations of the one or more RDLs are configured so that one or more of the built-up thin pillar structures 124 are electrically and mechanically connected to one or more corresponding thick pillar structures 128, with each set of electrically and mechanically connected thin pillar structure(s) 124, RDL metallizations, and thick pillar structure(s) 128 forming a corresponding dual-sided stud structure 112.

At block 408, the built-up thick pillar structures 128 of the resulting workpiece 409 are overmolded with encapsulant to form a second encapsulant layer 413 (which, after singulation as described below, becomes the second encapsulant layer 114-2) that encapsulates the thick pillar structures 128 and a surface grind process is performed at the top surface of the workpiece 409 to provide a substantially planar and level surface, with this surface grind process removing some of the second encapsulant layer and the over-built regions of the thick pillar structures 128 (up to line 411), resulting in workpiece 415 having a planar mounting surface at which the top surfaces of the thick pillar structures are exposed.

Turning now to FIG. 5, the method 400 continues at block 410 with the workpiece 415 subjected to a backside lamination process in which the array of instances of workpiece 415 is removed from the panel carrier and, in some embodiments, a protective BSL layer 417 (which will become BSL layer 116 after singulation) is formed at the “backside” surface (that is, proximate to the IC die 104) so as to protect the IC die 104, resulting in an array of instances of workpiece 419. Other backside processes, such as laser marking, stamping, etc., also may be performed.

As shown by FIG. 5, in the reconstructed panel (panel 421) adjacent instances of the workpiece 419 may be fabricated such that a wider pillar structure is formed to provide for two adjacent thick pillar structures 128 that each are in a different instance of the workpiece 419 and will be so separated during the panel singulation process. To illustrate, the depicted panel 421 includes two adjacent workpieces 419-1 and 419-2, and implements a single wider pillar structure 423 that, after singulation, will result in a corresponding thick pillar structure 128 for the workpiece 419-1 and a separate corresponding thick pillar structure 128 for the workpiece 419-2. The method 400 can leverage this use of a single wider pillar structure that will subsequently be singulated into two separate thick pillar structures to facilitate the wettable sidewall flank formation process by, at block 412, forming grooves, such as groove 425, at the singulation lines, or boundaries, between instances of the workpiece 419 in the panel 421 at which singulation will occur to separate panel 421 into separate, individual packages. The grooves so formed have dimensions compatible with the desired dimensions of the sidewall flanks that subsequently result from the grooves. The grooves may be formed using, for example, in which a singulation blade having a kerf with the desired groove thickness is used to cut a partial-cut to the desired groove depth. As another example, a chemical etching process may be employed to obtain grooves of the desired dimensions in the wider pillar structures at the boundaries between workpieces. A similar singulation saw cut or chemical etch process may be employed at the edges of the instances of the workpieces 419 at the perimeter of the panel 421. Further, a CVP process, PVD process, or other well-known process may be employed to deposit gold (Au), tin (Sn), or another appropriate solder plating material on the top surface of the panel 421 so as to form a solder plating layer (omitted from FIG. 5, see solder plating layer 146, FIG. 1) on the exposed top and sidewall surfaces of the thick pillar structures 128.

At block 414, a saw-based or laser-based singulation process is performed to singulate the individual instances of the workpieces 419, such as along singulation line 427. Each singulated workpiece 419 thus becomes a corresponding instance of the semiconductor package 102, such as workpieces 419-1 and 419-2 becoming semiconductor packages 102-1 and 102-2, respectively. Each instance of the semiconductor package 102 then may be subjected one or more chip sorting or other testing processes so as to identify known-good packages suitable for use for their intended purposes.

Note that not all of the activities or elements described above in the general description are required, that a portion of a specific activity or device may not be required, and that one or more further activities may be performed, or elements included, in addition to those described. Still further, the order in which activities are listed are not necessarily the order in which they are performed. Also, the concepts have been described with reference to specific embodiments. However, one of ordinary skill in the art appreciates that various modifications and changes can be made without departing from the scope of the present disclosure as set forth in the claims below. Accordingly, the specification and figures are to be regarded in an illustrative rather than a restrictive sense, and all such modifications are intended to be included within the scope of the present disclosure.

Benefits, other advantages, and solutions to problems have been described above with regard to specific embodiments. However, the benefits, advantages, solutions to problems, and any feature(s) that may cause any benefit, advantage, or solution to occur or become more pronounced are not to be construed as a critical, required, or essential feature of any or all the claims. Moreover, the particular embodiments disclosed above are illustrative only, as the disclosed subject matter may be modified and practiced in different but equivalent manners apparent to those skilled in the art having the benefit of the teachings herein. No limitations are intended to the details of construction or design herein shown, other than as described in the claims below. It is therefore evident that the particular embodiments disclosed above may be altered or modified and all such variations are considered within the scope of the disclosed subject matter. Accordingly, the protection sought herein is as set forth in the claims below.

What is claimed is:

1. A leadless semiconductor package comprising:
an integrated circuit (IC) die having one or more contacts at an active surface facing a mounting surface of the leadless semiconductor package; and
a plurality of dual-sided stud structures providing electrical connectivity between the IC die and the mounting surface, each dual-sided stud structure having at least one first conductive pillar structure extending from a corresponding contact at the active surface to a redistribution layer and having at least one second conductive pillar structure extending from a redistribution layer to an edge of the mounting surface, each first conductive pillar structure having a first dimension in a direction parallel to the mounting surface that is less than a corresponding second dimension of each second conductive pillar structure.

2. The leadless semiconductor package of claim 1, further comprising encapsulant material at least partially encapsulating the IC die and the plurality of dual-sided stud structures.

3. The leadless semiconductor package of claim 2, wherein the encapsulant material includes:
a first encapsulant layer encapsulating the active surface of the IC die and the first pillar structures of the plurality of dual-sided stud structures; and
a second encapsulant layer encapsulating the second pillar structures of the plurality of dual-sided stud structures and forming a portion of the mounting surface.

4. The leadless semiconductor package of claim 1, wherein each second conductive pillar structure comprises a solder wettable flank at an exterior sidewall.

5. The leadless semiconductor package of claim 4, further comprising solder plating on exterior surfaces of the second conductive pillar structures that are parallel to the mounting surface and on surfaces of the solder wettable flanks of the second conductive pillar structures.

6. The leadless semiconductor package of claim 1, wherein the second dimension is at least two times larger than the first dimension.

7. The leadless semiconductor package of claim 1, wherein the second dimension is at least three times larger than the first dimension.

8. An electronic device comprising a circuit board having the leadless semiconductor package of claim 1 mounted thereon.

9. A leadless semiconductor package comprising:
a first surface and an opposing second surface;
an integrated circuit (IC) die disposed adjacent to the first surface; and
a conductive fan-out structure to provide contact fan-out from a plurality of contacts of an active surface of the IC die to the second surface of the leadless semiconductor package, the conductive fan-out structure comprising:
a plurality of thick pillar structures, each thick pillar structure extending into the leadless semiconductor package from an edge of the second opposing surface, wherein exposed surfaces of the thick pillar structures serve as surface mounting pads for the leadless semiconductor package; and
a plurality of thin pillar structures, each thin pillar structure extending into the leadless semiconductor package from a corresponding contact of the plurality of contacts and electrically connected to at least one thick pillar structure via at least one redistribution layer, wherein the thick pillar structures are at least two times as thick as the thin pillar structures.

10. The leadless semiconductor package of claim 9, wherein each second conductive pillar structure comprises a solder wettable flank formed at an exterior sidewall.

11. The leadless semiconductor package of claim 9, further comprising:
at least one encapsulant layer encapsulating the plurality of thin pillar structures and the plurality of thick pillar structures.

12. An electronic device comprising a circuit board having the leadless semiconductor package of claim 9 mounted thereon.

13. A method of fabricating a leadless semiconductor package, the method comprising:
forming a plurality of first pillar structures extending from contacts at an active surface of an integrated circuit (IC) die;
encapsulating the IC die and the plurality of first pillar structures in a first encapsulant layer;
forming one or more redistribution layers at a surface of the first encapsulant layer opposite the IC die, the one or more redistribution layers having metallizations electrically and mechanically connected to one or more corresponding first pillar structures of the first plurality of pillar structures;
forming a plurality of second pillar structures extending from the one or more redistribution layers, each second pillar structure electrically connected to one or more first pillar structures via at least one redistribution layer and having a second dimension in a direction parallel to the active surface that is greater than a corresponding first dimension of each first conductive pillar structure;
encapsulating the plurality of second pillar structures in a second encapsulant layer; and
planarizing the second encapsulant layer and the plurality of second pillar structures to form a mounting surface for the leadless semiconductor package with exposed surfaces of the plurality of the second pillar structures serving as surface mount pads for the leadless semiconductor package.

14. The method of claim 13, further comprising:
forming solder wettable flanks in exposed sidewalls of the plurality of second pillar structures.

15. The method of claim 14, further comprising:
solder plating exposed surfaces of the plurality of the second pillar structures including the solder wettable flanks.

16. The method of claim 14, further comprising:
forming a reconstructed panel comprising a plurality of workpieces including a workpiece representing the leadless semiconductor package;
singulating the reconstructed panel after planarizing the second encapsulant layer and the plurality of second pillar structures to generate a plurality of leadless semiconductor packages from the plurality of workpieces; and
wherein forming the solder wettable flanks comprises forming grooves along singulation lines in metal material representing second pillar structures from adjacent workpieces prior to singulating the reconstructed panel.

17. The method of claim 16, wherein forming grooves comprises at least one of:
performing chemical etches to form the grooves; or performing singulation cuts to partial depth to form the grooves.

18. The method of claim 13, wherein the second dimension is at least two times the first dimension.

19. The method of claim 13, wherein the second dimension is at least three times the first dimension.

20. A leadless semiconductor package formed in accordance with the method of claim 13.
